(19) United States
(12) Patent Application Publication
(10) Pub. No.: US 2012/0086113 A1
(43) Pub. Date: Apr. 12, 2012

(54) FLEXIBLE CIRCUITS AND METHODS FOR MAKING THE SAME

(76) Inventors: Brian Smith, Cambridge, MA (US); Maria Cardoso, Cambridge, MA (US)

(21) Appl. No.: 13/267,688

(22) Filed: Oct. 6, 2011

Related U.S. Application Data
(60) Provisional application No. 61/390,282, filed on Oct. 6, 2010.

(51) Int. Cl. H01L 23/28; H01L 21/56

(52) U.S. Cl. 257/687; 438/124; 438/126; 257/E23.116; 257/E23.141; 257/E21.502

(57) ABSTRACT

Embodiments of the invention relate to a method for creating a flexible circuit, including defining a cavity in a top surface of a substrate before disposing a semiconductor chip within the cavity, such that a backside of the chip is disposed beneath the top surface of the substrate and above a bottom surface of the cavity. The method also includes forming a flexible connecting layer on the top surface of the substrate and extending over the chip. Other embodiments relate to a flexible circuit including a substrate defining a cavity in a top surface thereof. The cavity has encapsulant and a chip disposed therein, wherein a frontside of the chip is substantially coplanar with the top surface of the substrate. A flexible connecting layer is disposed on the top surface of the substrate and is partially supported by the substrate.

### PRIORITY CLAIM

This application claims priority to and the benefit of U.S. Provisional Patent Application Ser. No. 61/390,282, filed on Oct. 6, 2010, the disclosure of which is hereby incorporated herein by reference in its entirety.

### FIELD OF THE INVENTION

This application relates to flexible circuits and, more particularly, to flexible circuits including a flexible layer formed after disposing a chip in a substrate.

### BACKGROUND OF THE INVENTION

In many applications, especially high input/output applications such as video, high resolution sensing, and application-specific integrated circuit (ASIC)/field-programmable gate array (FPGA) based data processing, the necessary components are typically attached to a rigid, organic board with a traditional interconnect. In video applications, to achieve a greater field of view, an imager is often placed on a gimbal to allow for movement. This approach may require a relatively large, heavy packaging solution, that constrains system weight and power (SWAP) budgets. This packaging may inhibit deployment in mobile applications. Further, the lack of modularity and miniaturization may reduce options for expanding the functionality of a particular circuit, and may result in redundant features when multiple circuits are linked together.

A flexible circuit may be used to provide some movement of linked components relative to each other. Often, the flexible circuit is provided and the components are added to the flexible circuit. The components are typically spaced far enough apart to allow for connections to be made to the flexible circuit, such as by soldering. This spacing may result in gaps of images (where imagers are used), and the size of the connections may make the circuit more difficult to closely adhere to a curved surface.

There is therefore a need for a flexible circuit with less space between components that is modular and useful in a wide range of applications.

### SUMMARY OF THE INVENTION

In some embodiments, the flexible circuit of the present invention provides a way to assemble imagers, sensors, and other components, including many commercial off-the-shelf components, at wafer scale with high density input/output. This may be achieved through the use of spin-on polymers that allow the definition of approximately 5 to 10 μm feature sizes. Accordingly, the lines and spaces achieved using spin-on polymer technology may be approximately 2 to 20 times smaller than what is found in typical flexible electronic circuits.

The flexible circuit of embodiments of the present invention may be made by disposing chips in cavities of a substrate, spinning-on a flexible polymer, and then removing sections of the substrate between the chips. The spun-on polymer may be compatible with most electronics material systems, including low density commercial laminate flex, ceramic, and silicon, and may have high-density lines interconnecting the chips, which helps enable the integration of the circuit into a wide range of applications. A flexible circuit created in this manner may have an approximately 50 to 1000 times volume reduction when compared to traditional military grade surface mount technology (SMT) electronics. Further, the per-die packaging cost may be reduced as a full wafer of interconnects and chip attachment may be defined simultaneously when spinning-on and patterning the polymer.

The resultant flexible circuit may provide a smaller size, an increased modularity, and a reduced weight. The close spacing of the chips and other components allows for higher integration density. The thinned silicon does not compromise the performance of the components, and enables systems incorporating the components to be more robust. The flexible circuit may be used in a wide range of applications, such as foldable devices where the chips and components are arranged in a three-dimensional network, allowing full areal scalability. Other applications include 360° field of view imaging, flexible hybrid multiple-chip modules, and ultra miniature electronics for intelligence, surveillance and reconnaissance (ISR) applications, just to name a few.

In one aspect, embodiments of the invention relate to a method for creating a flexible circuit. The method includes defining a cavity in a top surface of a substrate before disposing a semiconductor chip within the cavity, such that a backside of the chip is disposed beneath the top surface of the substrate and above a bottom surface of the cavity. The method also includes forming a flexible connecting layer on the top surface of the substrate. The flexible connecting layer extends over the chip.

One or more of the following features may be included. Forming the cavity may include etching a portion of the substrate. The substrate may include or consist essentially of silicon, quartz, glass, diamond, sapphire, ceramic, silicon carbide, and/or low expansion metal. Disposing the chip may include substantially filling the cavity with encapsulant. Disposing the chip may include aligning a frontside of the chip parallel to the top surface of the substrate; the frontside of the chip and the surface of the substrate may be substantially coplanar.

Forming the flexible connecting layer may include spinning on a polymeric material onto the top surface of the substrate. The polymeric material may include or consist essentially of benzocyclobutene, polyimide, and/or acrylic. The chip may be secured to a film prior to disposing the chip in the cavity. Disposing the chip may include positioning the film over the cavity such that the chip is disposed in a predetermined location in the cavity. At least a portion of the substrate may be removed after the chip is disposed in the cavity. The substrate may have a bottom surface opposite and substantially parallel to the top surface of the substrate, and removing the portion of the substrate may include removing a portion of the bottom surface. After forming the flexible connecting layer, a conductive interconnect to the chip may be defined. The interconnect may have multiple layers.

In another aspect, embodiments of the invention relate to a flexible circuit. The flexible circuit includes a substrate defining a cavity in a top surface of the substrate. The cavity has encapsulant disposed therein. The flexible circuit also includes a chip disposed in the cavity, wherein a frontside of the chip is substantially coplanar with the top surface of the substrate, and a flexible connecting layer disposed on the top surface of the substrate, wherein the substrate supports at least a portion of the flexible connecting layer.

One or more of the following features may be included. The substrate may define a plurality of cavities. The substrate may be discontinuous between at least two cavities. The flexible connecting layer may extend at least partially over the chip. A conductive interconnect may be defined on the flexible connecting layer. A plurality of chips may be disposed in the cavity.

### BRIEF DESCRIPTION OF THE DRAWINGS

There are shown in the drawings embodiments that are presently preferred, it being understood, however, that the invention is not limited to the precise arrangements and configurations shown.

FIG. 1 is a schematic, cross-sectional view of a substrate for use in creating a flexible circuit, in accordance with one embodiment of the invention;

FIG. 2 is a schematic, cross-sectional view of chips disposed in cavities in the substrate depicted in FIG. 1, in accordance with one embodiment of the invention;

FIG. 3 is a schematic, cross-sectional view of the chip depicted in FIG. 2 encapsulated in the substrate depicted in FIG. 1, in accordance with one embodiment of the invention;

FIG. 4 is a schematic, cross-sectional view of the substrate depicted in FIG. 3 with a mask on a bottom surface thereof, in accordance with one embodiment of the invention;

FIG. 5 is a schematic, cross-sectional view of the substrate depicted in FIG. 4 with a flexible connecting layer on a top surface thereof, in accordance with one embodiment of the invention;

FIG. 6 is a schematic, cross-sectional view of the substrate depicted in FIG. 5 with a conductive interconnect, in accordance with one embodiment of the invention;

FIG. 7 is a schematic, cross-sectional view of the substrate depicted in FIG. 6 with sections removed from the bottom surface thereof, in accordance with one embodiment of the invention;

FIG. 8 is a schematic, cross-sectional view of the substrate depicted in FIG. 7 with additional components disposed thereon, in accordance with one embodiment of the invention; and

FIG. 9 is a schematic, top view of a flexible circuit including the substrate depicted in FIG. 7, in accordance with one embodiment of the invention.

### DETAILED DESCRIPTION OF THE INVENTION

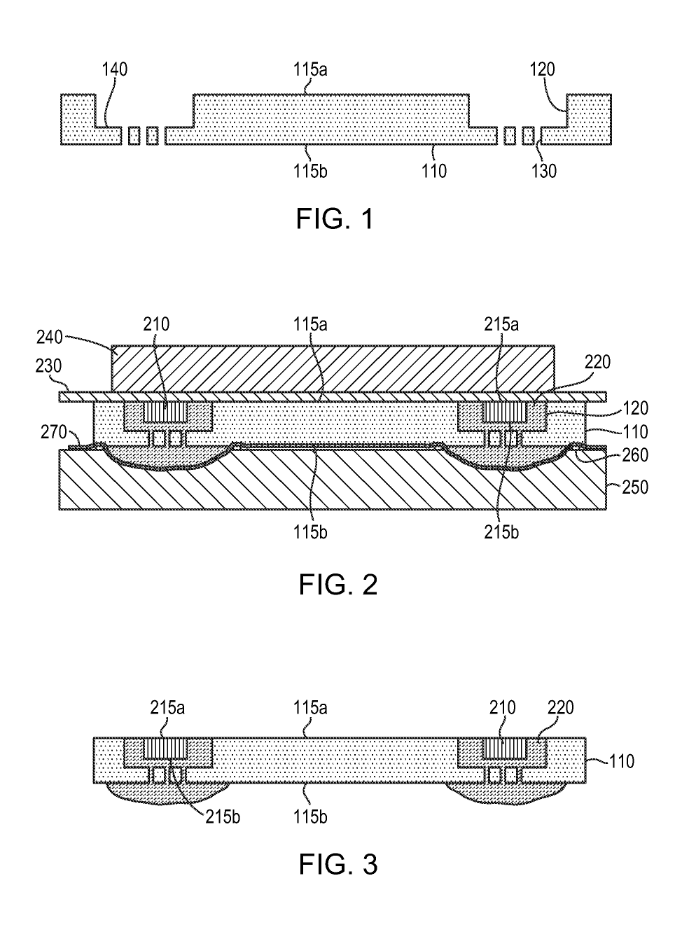

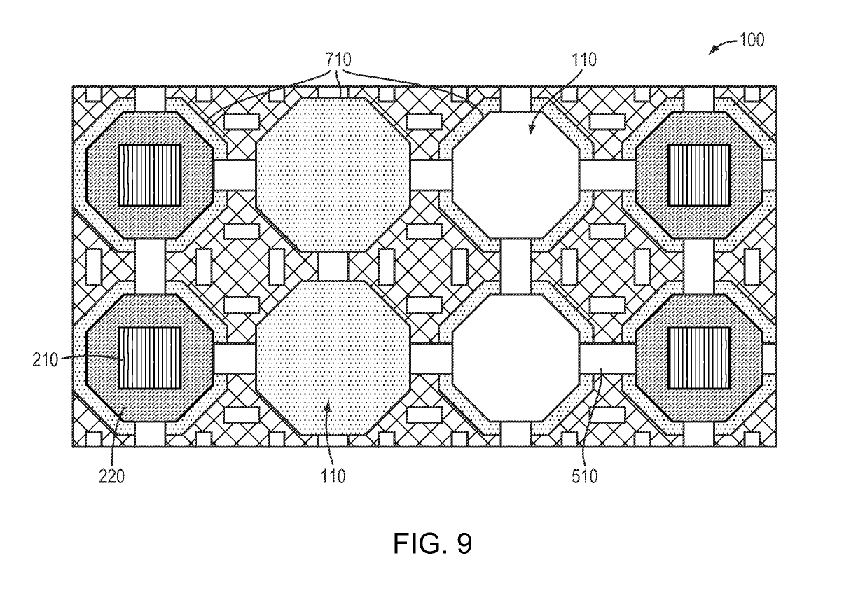

Referring to FIG. 1, a flexible circuit 900 (depicted in FIG. 9) may be fabricated as follows. A substrate 110 is provided. The substrate 110 may be a wafer formed of a rigid material. The wafer may be circular with approximately a 20-400 micrometer diameter and an approximately 500 micrometer thickness, although sizes beyond this range are also contemplated. Other wafers may be rectangular, triangular, square, and other shapes. The wafer may be approximately 100-1000 micrometers thick, though in some embodiments the wafer may fall outside of this range. In some embodiments, the substrate may be formed from a material that may be patterned to form semiconductor devices. Accordingly, the substrate 110 may include or consist essentially of silicon, quartz, glass, diamond, sapphire, ceramic, silicon carbide, and/or low expansion metal. Other possible substrate materials include amorphous silicon dioxide and various metals and ceramics, and combinations thereof. The substrate 110 may be formed from a single material and may be formed from a combination of materials.

A cavity 120 may be defined in a top surface 115a of the substrate 110. The cavity 120 may be formed by, for example, conventional photolithographic methods, and may include etching a portion of the substrate by, e.g., either a wet etch or a dry etch. Suitable etching techniques include deep reactive-ion etching (DRIE), chemical etching, and plasma-based reactive ion etching. For certain substrate materials, such as non-silicon materials, other cavity 120 forming processes may be used, including certain mechanical processes (e.g., milling, cutting, or stamping). Some processes may be used to create substantially vertical sidewalls for the cavity 120. The cavity 120 may be sized to receive a semiconductor chip 210 (depicted in FIG. 2) therein. The chip 210 may comprise or consist essentially of an ASIC, FPGA, or some other CMOS component. The chip 210 may also comprise or consist essentially of GaAs, GaAn, CCD, or more exotically MEMS, power generating, crystal, or passive (resistor, capacitor, inductor) devices. The size and shape of the cavity 120 may be determined by thermomechanical (stress) considerations. For example, the cavity may be approximately 1 cm×1 cm, and may be as large as the size of the substrate or as small as 100 micrometers and smaller. The cavity 120 may also be one of several differently shaped volumes, such as cylindrical, a rectangular prism, a triangular prism, or other. The shape of the cavities 120 may also be defined by the desired footprint of the final flexible circuit 900. The cavities 120 may define a pattern across the substrate, such as grid, or diamond, subject to the same considerations as determining the shape of the cavities 120. Holes 130 may be created in a bottom surface 115b of the substrate 110 (which may be substantially parallel to the top surface 115a of the substrate 110), extending through the substrate 110 to a bottom surface 140 of the cavity 120, thereby creating a passage for flow to the cavity 120. Fill holes 130 are preferably formed in substrate 110 by forming a protective layer (not shown), e.g., photoresist, over top surface 115a and bottom surface 115b, e.g., by a spin-on process. The protective layer on bottom surface 115b is then patterned, e.g., by conventional masked photolithography, such that areas of bottom surface 115b where fill holes 130 are to be fabricated are substantially free of the protective layer. Fill holes 130 are subsequently formed by, e.g., plasma or wet etching. In a preferred embodiment, fill holes 130 do not completely penetrate to front surface 115a of substrate 110, and have a depth in the range of approximately 200 μm to approximately 400 μm. The remaining thickness between the bottoms of fill holes 130 and top surface 115b may be approximately 150 μm. In an embodiment, each fill hole 130 has a diameter of approximately 1 mm. The holes 130 may be sized for optimal flow of encapsulant 220 (described and depicted beginning in FIG. 2) or other injection molding materials.

FIG. 2 depicts a step of disposing a chip 210 within the cavity 120 as part of the flexible circuit fabrication process. A plurality of chips 210 may be disposed over an adhesive film 230 (e.g., an acrylic adhesive), although, more generally, as few as a single chip 210 may be disposed over the adhesive film 230. In an embodiment, one chip 210 is disposed over the film for each cavity 120 prepared in substrate 110 as described above. Each chip 210 may include or consist essentially of at least one semiconductor material such as Si, GaAs, or InP, and may be a bare die or a packaged die. In an embodiment, at least one chip 210 is a packaged assembly of multiple devices, e.g., a hermetically packaged sensor and/or microelectromechanical systems (MEMS) device. In various embodiments, each chip 210 is a microcontroller, a central processing unit, or other type of chip utilized in various electronic components such as sensors or computers. Chips 210 may have non-uniform thicknesses, and may differ in size and shape—because the chips 210 may be encapsulated in cavities 120 as described below, individually tailored recesses or plinths may not be required for cavities 120 to be suitable to contain a wide range of chips 210, or even multiple chips 210 that may be arranged in many positions within each cavity 120, including side by side. A frontside 215a which typically contains circuitry fabricated thereon, is in contact with the adhesive film 230.

In order to facilitate accurate placement of the chips 210, the adhesive film 230 may be placed over a die placement mask containing features corresponding to the pattern of cavities 120 defined on the substrate 110. The adhesive film 230 may be preferably at least partially transparent, and, as such, the chips 210 may be placed on the adhesive film 230 in locations defined on the die placement mask thereunder. The adhesive film 230 may include or consist essentially of a substantially transparent material (e.g., MYLAR or KAPTON), and it may be supported around its perimeter by an alignment ring. In an embodiment, the alignment ring includes or consists essentially of a rigid material such as a metal.

The chips 210 adhered to the adhesive film 230 may be placed over and aligned to cavities 120 in the substrate 110. Substrate 110 may be disposed over a hotplate and within a diaphragm. Once the chips 210 are aligned to the cavities 120, the alignment ring may be lowered such that the adhesive film 230 contacts a top surface 115a of the substrate 110 and the chips 210 are substantially disposed within the cavities 120. A substantial vacuum may be drawn in the space between the film and the substrate 110 (now “sealed” due to the contact between the diaphragms) such that the adhesive film 230 preferably (and substantially uniformly) contacts the top surface 115a of the substrate 110. Thus, the adhesive film 230 “seals” the chips 210 within the cavities 120, as shown in FIG. 2, in a predetermined position (e.g., coplanar and parallel with the top surface of the substrate 110) and predetermined location (in three-dimensional space). In an embodiment, the chips 210 adhere to the adhesive film 230 within the cavities 120, but not to an internal surface of the cavities 120.

An encapsulation chamber may be utilized to encapsulate the chips 210 within the cavities 120. The substrate 110, now adhered to the adhesive film 230 (which itself is disposed on the alignment ring) is placed within the encapsulation chamber. Additionally disposed within the encapsulation chamber, on opposing sides of the substrate 110, are platen 250 and pressure plate 240. At least one o-ring 260 is disposed over platen 250, and a film 270 is disposed over platen 250 and o-rings 260, thus forming pockets. Each pocket may contain encapsulant 220. Platen 250 preferably includes or consists essentially of a rigid material, e.g., a metal, and is heatable. O-rings 260 may include or consist essentially of an elastomeric material such as silicone, and film 270 may include or consist essentially of Teflon. Platen 250 also includes holes suitable for the conduction of compressed gas (e.g., compressed air), as described further below. The introduction of compressed gas through holes applies pressure to the back surface of film 270 in the pockets, and the film 270 may deflect in response to the applied pressure. The encapsulation chamber may also include a vacuum port connected to a vacuum pump that enables the evacuation of the encapsulation chamber.

In an exemplary embodiment, the chips 210 are encapsulated according to the following steps. First, the platen 250 is heated to approximately 30° C. and the encapsulation chamber is evacuated for approximately 5 minutes in order to out-gas the encapsulant 220. The vacuum in the encapsulation chamber also substantially prevents the formation of trapped air bubbles in the cavities 120 during encapsulation of the chips 200 (as described below). The fill holes are aligned above the pockets, and force is applied to the pressure plate 240 in order to seal a bottom surface 115b of the substrate 110 to the o-rings 260 covered with the film 270. A pressure of approximately 15 pounds per square inch (psi) is applied to the back surface of the film 270 via the introduction of compressed gas through the holes, thus forcing the encapsulant 220 through fill holes 130 into the cavities 120. The adhesive film 230, supported by pressure plate 240, at least substantially prevents the flow of encapsulant 220 between chips 210 and the adhesive film 230, maintaining the substantial coplanarity of the top surfaces of the chips 210. The pressure is applied for approximately 5 minutes, whereupon the pressure is reduced to, e.g., approximately 1 psi. The platen 250 is heated to approximately 60° C. for a time period sufficient to at least substantially cure the encapsulant 220, e.g., approximately 4 hours. As the encapsulant 220 cures, its volume may be reduced, and the pressure applied to the film 270 may be sufficient to inject additional encapsulant 220 into the cavities 120. Thus, the cavities 120 are continuously filled with encapsulant 220 during curing, ensuring that the cavities 120 are substantially or completely filled with encapsulant 220 after curing. The substrate 110 is then removed from the encapsulation chamber, and excess encapsulant 220 present on the bottom surface 115b of the substrate 110 (shown in FIG. 3) may be removed by, e.g., scraping with a razor blade and/or application of a suitable solvent. Curing may be continued at a temperature of approximately 60° C. for a period of approximately 3 hours to approximately 5 hours. Higher curing temperatures, such as 80° C. and greater, may also be used, and may achieve the same cured state in a shorter amount of time. Once the encapsulant 220 is cured, the adhesive film 230 is then removed from the substrate 110. After removal of the adhesive film 230 (e.g., by peeling off), the exposed top surface 115a of the substrate 110 and the frontside of the chips 210 is preferably planar to within ±2 μm. In other embodiments, other techniques are utilized to introduce encapsulant 220 into cavities 120. For example, a syringe, an injection-molding screw, or a piston pump may be utilized to introduce encapsulant 220 into cavities 120 through fill holes 130. A dielectric layer (e.g., a flexible layer 510) may later be formed (e.g., spin-coated) over the top surface 115a of the substrate 110 and the encapsulated chips 210 (see FIG. 5). In various embodiments, any metal and/or oxide layers present on the surface of substrate 110 between the encapsulant-containing cavities 120 may be stripped prior to formation of the flexible layer 510, thereby promoting improved adhesion thereof.

In an exemplary embodiment, encapsulant 220 includes or consists essentially of a filled polymer such as molding epoxy. The filler may reduce the thermal expansion of the polymer, and may include or consist essentially of minerals, e.g., quartz, in the form of particles, e.g., spheres, having characteristic dimensions, e.g., diameters, smaller than approximately 50 micrometers. Encapsulant 220 may be an insulating material having a coefficient of thermal expansion (CTE) approximately equal to the CTE of silicon. Encapsulant 220 may be present in the pockets in the form of a paste or thick fluid, or in the form of a powder that melts upon application of pressure thereto. Subsequent processing may cure/crosslink encapsulant 220 such that it becomes substantially rigid. In various embodiments, encapsulant 220 includes or consists essentially of a heavily filled material such as Shin-Etsu Semicoat 505 or SMC-810.

In certain embodiments, one or more passive components such as resistors, capacitors, and/or inductors may be encapsulated within substrate 110 instead of or in addition to a chip 210. Modules including such passive components may be used as, e.g., high-density interconnect (HDI) substrates. The HDI substrates (and the passive components therein) may in turn be electrically connected to platforms such as circuit boards, and may themselves function as platforms for one or more electronic component or module.

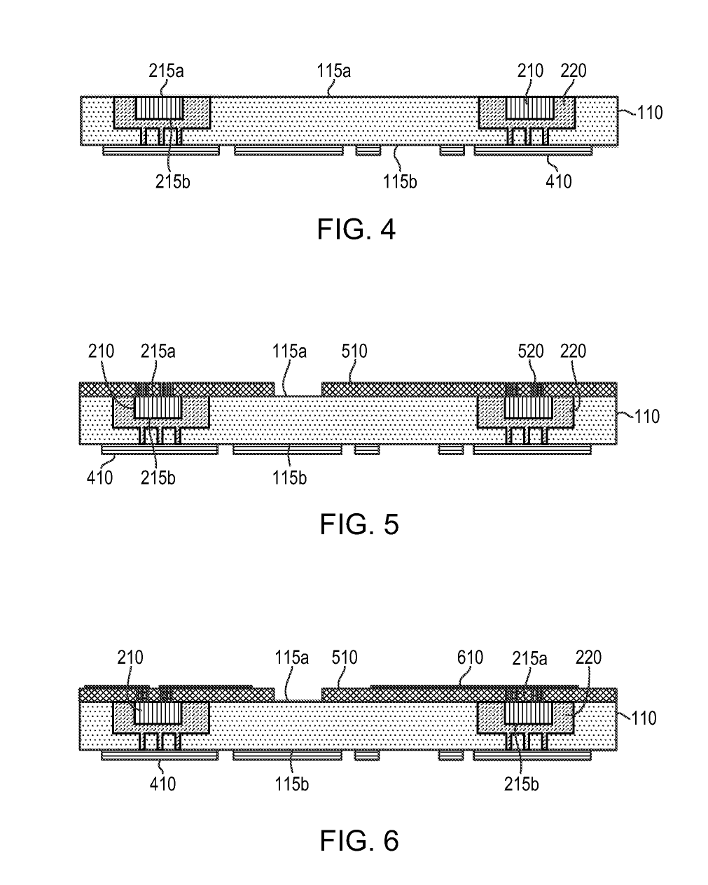

Referring to FIG. 4, a mask 410 is then applied to the bottom surface 115b of the substrate 110. The mask 410 may be applied to cover the whole, or substantially the whole, bottom surface of the substrate 110, and then areas of the mask 410 may be removed, e.g., in a pattern through photolithographic techniques using a photoresist. The pattern may be made by wet or dry etching the mask 410. Alternatively, the mask 410 may be applied in sections to substrate 110. Areas of the substrate 110 not covered by the mask 410 may eventually be removed, as described below. The mask 410 may be made of any etch-resistant material, such as an oxide, metal, or polymer, depending on the etching process to be used. Silicon dioxide may also be used.

A flexible connecting layer 510 is formed on the top surface of the substrate 110, as depicted in FIG. 5. The flexible layer 510 may also extend over sections of the chips 210 and the encapsulant 220. The flexible layer 510 may be formed by spinning a material onto the top surface of the substrate 110. The flexible layer 510 may also be formed by laying materials onto the substrate 110. The flexible layer 510 may be made formed with many dielectric materials, including, but not limited to, benzocyclobutene, polyimide (such as those available from HD MicroSystems™), acrylics, epoxies, and other polymers. The material selection may be driven by film stress, cure temperature, glass transition temperature, and other considerations. Once the flexible layer 510 is on the substrate 110, the flexible layer 510 may be patterned (e.g., with photolithography) to connect only certain areas of the substrate or to remove excess material. Material from the flexible layer 510 may also be removed to provide access to the chips 210, creating conduits 520 between the chips 210 and a top surface of the flexible layer 510. These conduits 520 may be formed at the same time with the same processes as above or alternate techniques including, but not limited to, etching, laser drilling and mechanical punching. The flexible layer 510 may be applied before, concurrent with, or after the application of the mask 410.

Once the conduits 520 are formed, they may be plated to help provide electrical connections to the chips 210. A conductive interconnect 610 may then (or concurrently) be defined along the top surface of the flexible layer 510 and within the conduits 520, as depicted in FIG. 6. The conductive interconnect 610 may be formed from a metal by any of many known processes, such as plating, sputtering, and evaporation, followed by photolithographic patterning and etching. These processes may result in a thin, unified interconnect 610 extending between chips 210, as well as other components 810 (depicted in FIG. 8 and discussed below), and/or power sources, such as surface mounted batteries, thin film power sources, or energy harvesting structures that may be chips in the substrate. Discrete lines in the interconnect 610 for making connections may be defined through various process, such as photolithography. In certain embodiments the interconnect 610 may be formed from multiple layers.

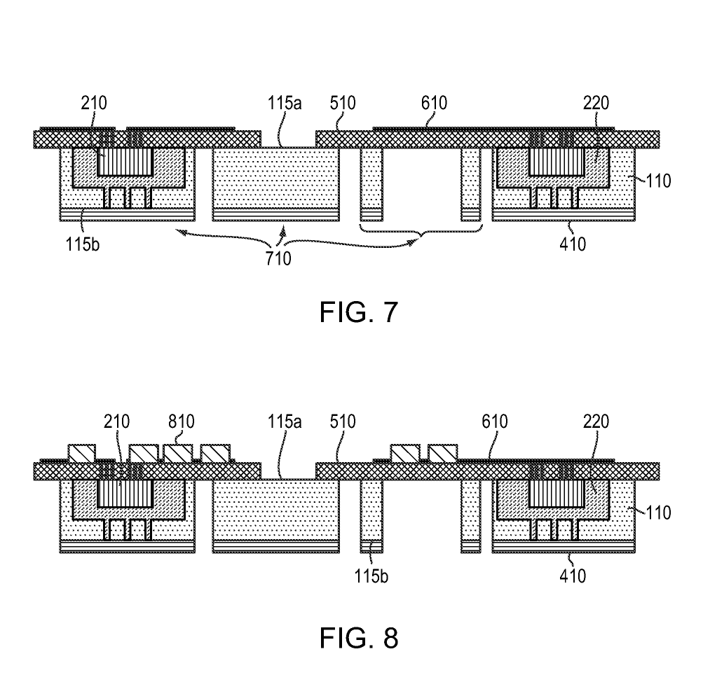

FIG. 7 depicts the substrate 110 separated into discrete, discontinuous segments 710 connected by the flexible layer 510. The substrate 110 may be removed in the areas without the mask 410 through a process such as wet and/or dry etching (e.g., the etching processes described above). In some embodiments, the substrate 110 may be thinned to facilitate the etching process. Without substrate 110 connecting the various segments 710, the segments 710 may move in relation to each other while still being connected. This allows for deployment in a number of environments, especially on curved surfaces. The segments 710 may be spaced apart approximately 1 mm, and may be spaced apart as much as allowed by the size of the original substrate or more, or as little as 100 micrometers or less.

FIG. 8 depicts additional components 810 mounted on the upper surface of the circuit; the components 810 may be in contact with the interconnect 710. The components 810 may be optical components, oven-controlled crystal oscillators (OCXOs), large passive devices, and batteries, amongst others. These components 810 may be surface mounted at the end of the process due to size or temperature considerations. For example, at various points in the process, and particularly when injecting the encapsulant 220, high temperatures (e.g., approximately 180° C. to approximately 400° C.) may be reached, and may be dependent upon the glass transition temperature of the materials being used. Surface mounting the components 810 at the end of the process avoids exposure to these temperatures.

A top view of a flexible circuit 900 is depicted in FIG. 9. The exemplary illustrated flexible circuit 900 does not include any additional components 810, however they may be mounted at any time. Some circuits 900 may include only a single segment 710. Each of the segments 710 may be defined by a portion of the substrate 110 extending at least along a perimeter of the segment 710. This perimeter may also define any of a number of shapes, including an octagon as depicted in FIG. 9, a square, a circle, or any other shape. The separate segments 710 may be distributed in a variety of patterns, such as a grid, diamond, or irregular shape. The rigidity of the substrate 110 may help provide support for mounting the components 810. Some of the segments 710 may be solid substrate 110, allowing for the mounting of additional components 810 on the interconnect 610. The rigidity provided by the substrate 110 in the segments 710 may also provide some structural support for the overall flexible circuit 900. This is especially true when nothing is disposed within a segment 710, as may be desirable to help thermally isolate adjacent chips 210 or other components 810.

While there have been described herein what are to be considered exemplary and preferred embodiments of the present invention, other modifications of the invention will become apparent to those skilled in the art from the teachings herein. The particular methods of manufacture and geometries disclosed herein are exemplary in nature and are not to be considered limiting. It is therefore desired to be secured in the appended claims all such modifications as fall within the spirit and scope of the invention. Accordingly, what is desired to be secured by Letters Patent is the invention as defined and differentiated in the following claims, and all equivalents.

What is claimed is:

1. A method for creating a flexible circuit, the method comprising the steps of:
defining a cavity in a top surface of a substrate;
thereafter, disposing a semiconductor chip within the cavity, such that a backside of the chip is disposed beneath the top surface of the substrate and above a bottom surface of the cavity;
forming a flexible connecting layer on the top surface of the substrate, the flexible connecting layer extending over the chip.

2. The method of claim 1, wherein forming the cavity comprises etching a portion of the substrate.

3. The method of claim 1, wherein the substrate comprises a material selected from the group consisting of silicon, quartz, glass, diamond, sapphire, ceramic, silicon carbide, low expansion metal, and combinations thereof.

4. The method of claim 1, wherein disposing the chip comprises substantially filling the cavity with encapsulant.

5. The method of claim 1, wherein disposing the chip comprises aligning a frontside of the chip parallel to the top surface of the substrate.

6. The method of claim 5, wherein disposing the chip comprises aligning the frontside of the chip with the top surface of the substrate such that the frontside of the chip and the top surface of the substrate are substantially coplanar.

7. The method of claim 1, wherein forming the flexible connecting layer comprises spinning on a polymeric material onto the top surface of the substrate.

8. The method of claim 7, wherein the polymeric material is selected from the group consisting of benzocyclobutene, polyimide, acrylics, and combinations thereof.

9. The method of claim 1 further comprising securing the chip to a film prior to disposing the chip in the cavity.

10. The method of claim 9, wherein disposing the chip within the cavity comprises positioning the film over the cavity such that the chip is disposed in a predetermined location in the cavity.

11. The method of claim 1 further comprising removing at least a portion of the substrate after the chip is disposed in the cavity.

12. The method of claim 11 wherein the substrate has a bottom surface opposite and substantially parallel to the top surface of the substrate, and removing the portion of the substrate comprises removing a portion of the bottom surface.

13. The method of claim 1 further comprising, after forming the flexible connecting layer, defining a conductive interconnect to the chip.

14. The method of claim 13, wherein the interconnect comprises a plurality of layers.

15. A flexible circuit comprising:
a substrate defining a cavity in a top surface thereof, the cavity having encapsulant disposed therein;
a chip disposed in the cavity, wherein a frontside of the chip is substantially coplanar with the top surface of the substrate; and
a flexible connecting layer disposed on the top surface of the substrate,
wherein the substrate supports at least a portion of the flexible connecting layer.

16. The flexible circuit of claim 15, wherein the substrate defines a plurality of cavities.

17. The flexible circuit of claim 16, wherein the substrate is discontinuous between at least two cavities.

18. The flexible circuit of claim 15, wherein the flexible connecting layer extends at least partially over the chip.

19. The flexible circuit of claim 15 further comprising a conductive interconnect defined on the flexible connecting layer.

20. The flexible circuit of claim 15 further comprising a plurality of chips disposed in the cavity.
